(19) United States
(12) Patent Application Publication
(10) Pub. No.: US 2010/0039062 A1
(43) Pub. Date: Feb. 18, 2010

(54) Smart charge system for electric vehicles integrated with alternative energy sources and energy storage

(76) Inventors: Gong-en Gu, San Ramon, CA (US); Chao Su, Pleasanton, CA (US); William Douglas Sterling, Pleasanton, CA (US)

Correspondence Address: HOWARD COHEN, 1105 THE ALAMEDA, BERKELEY, CA, 94707, US

(21) Appl. No.: 12/290,149

(22) Filed: Oct. 28, 2008

Related U.S. Application Data
(60) Provisional application No. 61/189,242, filed on Aug. 18, 2008.

(51) Int. Cl. H02J 7/00; G01R 21/133

(52) U.S. Cl. 320/101; 320/109; 705/412

(57) ABSTRACT

A charging system for electrical vehicle batteries has a smart charge power meter with a computer control system to measure and integrate the delivered electrical power, enable/disable the charging stations and make all of the other necessary purchasing transaction steps equivalent to a gas station operation. The system may collect electricity by using whatever alternative energy system is available or can be incorporated into the charging system when it is constructed. The system may store the collected electricity in a high capacity energy storage system. The charging takes place at a charging lot which is within a secure perimeter to assure safety and prevent vandalism. The siting of charging lots is chosen to coincide with locations where vehicles are usually parked for extended times (e.g., parking lots, businesses, etc.).

### CROSS-REFERENCE TO RELATED APPLICATIONS

This application claims the priority benefit of the filing date of U.S. Provisional Appl. No. 61/189,242, filed Aug. 18, 2008.

### FEDERALLY SPONSORED RESEARCH

Not applicable.

### SEQUENCE LISTING, ETC ON CD

Not applicable.

### BACKGROUND OF THE INVENTION

1. Field of the Invention

This invention relates to the recharging of rechargeable electrical vehicles and other large capacity portable electrical devices, as well as commercial models for providing recharging services to electrical vehicle operators and owners.

2. Description of Related Art

The rising cost of oil, and concerns about global climate change leads to an increasing demand for alternative energy solutions for transportation and other types of energy-consuming industries. For the individual consumer, the biggest problem is costs arising from the gasoline expense for their cars from daily commuting. This financial pressure is increasing as petroleum product prices are increasing globally, due in part to an greatly expanding demand in newly industrialized countries, which now compete with the older industrialized countries for scarce fuel resources. Major car manufacturers (such as Ford, Toyota, Honda and GM) have plans to market plug-in hybrid cars and fully electric vehicles in the near future. With this type of next generation plug-in hybrids and all-electric vehicles coming into the market in the next two years, consumers can effectively reduce the need and expense of combustion fuels and meanwhile reduce their greenhouse emissions. As a rule of thumb, electrical-only vehicles with a similar mass and performance to conventional internal combustion vehicles will typically require more than 100 kWH of stored energy to operate even for moderate distances.

Many vehicle recharging facilities have been proposed or are, under development. Typically, there is envisioned a curbside charging installation, arranged so that a driver may park at the curb adjacent to the charging installation, extend a power cable between the vehicle and charging installation, perform a credit/debit transaction, and leave the vehicle for some time while the vehicle battery is recharged. Although this arrangement appears simple and straightforward, it is also lacking in basic security features that are needed to protect the vehicle and the cable, which is carrying,large currents at dangerously high voltage (120 VAC or 240 VAC). Moreover, it is prudent to charge vehicle batteries in a location where the vehicles may be monitored, since occasional problems with batteries and their connections may cause overheating or fire.

With the increasing number of the plug-in type hybrids and electric cars on the road, it is reasonable to believe the demand for electric car charging stations (similar to the familiar gas station) will also increase. However, the business of recharging electric cars will be fundamentally different than refueling internal combustion vehicles, due to an unalterable factor: the electrical charging time for a reasonably sized electric vehicle battery is significantly longer than the gasoline refueling process. In gasoline filling stations, most are arranged so that a line of cars will form behind a row of one or more pumps, and the autos at the pumps will be filled to the extent the driver wishes, payment is made, and the vehicles drive off, allowing the next autos in the queue to gain access to the pump(s). This mode of operation is termed a serial queue, and it relies on relatively swift filling and payment processes.

Due to the fact that battery charging takes a much longer time, and that time varies based on the size of the battery and its state of discharge, the predominant serial queue system of gasoline stations must be abandoned in favor of larger scale parallel fueling (charging) stations. This change in service mode, in turn, introduces several new problems, including a much larger space requirement to park and secure the vehicles being charged, and the very significant electrical loading of the local power grid.

### Objects of the Invention

It is desirable to create a practical, secure commercial delivery system for the sale of electrical recharging services while solving the queuing problems created by relatively long recharge time requirements. In addition, it is desirable to avoid very high electrical charging current demand and simultaneously alleviate the overloading of the local power grid system when the system is recharging a large number of vehicles at the same time. Likewise, it is advantageous to obtain auxiliary power from local and on-site alternative sources to reduce the load on the power grid and have auxiliary sources that do not rely on transmission through the grid. Possible alternative electrical sources include photovoltaic arrays, wind energy, co-generation from waste heat sources, and other energy generation and storage means.

### BRIEF SUMMARY OF THE INVENTION

The present invention generally comprises a charging system for electrical vehicle batteries. The charging system enables the practical method and apparatus to supply charging services for vehicle batteries in a parallel queue arrangement.

The charging system has several salient aspects. First, the system collects electricity by using whatever alternative energy system is available or can be incorporated into the charging system when it is constructed. This may include a solar panel array installed over a building, such as a garage or parking lot for a shopping mall, office or public building; or wind turbine energy; or tidal water turbine source, as available at the site. These sources are integrated with whatever electrical power must be drawn from the local power grid, as needed and available.

Second, the system stores the collected electricity in a high capacity energy storage system using batteries, or super-capacitor arrays, kinetic energy devices such as flywheel generator hybrids or thermo-electrical steam to turbine generators. More than one type of these energy storage devices may be used and combined by smart power management devices.

Third, the system has a smart charge power meter with a computer control system to measure and integrate the delivered electrical power, enable/disable the charging stations and make all of the other necessary purchasing transaction steps equivalent to a gas station operation. The transaction data may include total KWH of energy delivered to the vehicle battery, time of service (particularly important if pricing is based on time-of-day), cost per KWH, total cost, and credit/debit transaction codes and numbers.

Fourth, the siting of recharging stations will be chosen to coincide with locations where vehicles are usually parked for extended times. Noting that cars are parked for long periods while the drivers are on business, at work, shopping, or dining, the parking structures and parking lots for malls, office buildings, restaurants, theatres, transit terminal points (commuter rail stations, for example), are all likely locations for a smart charging station. The convergence of the charging service function with the (necessary) parking function of some businesses creates a synergistic commercial effect, since people seeking a vehicle charge will likely patronize the business(es) surrounding the charging station, and people patronizing the businesses will seek the most convenient recharge for their vehicle.

Integrating energy storage and generation into the charging station also provides a synergistic result, in that the charging station can provide charging from some of its storage capacity and avoid overloading the electrical grid, particularly during prime times for electrical power usage. Likewise, alternative energy generators such as photocell arrays can produce power only in direct sunlight, and the storage facility provides storage for use at other times of day. And the proprietary electrical power storage facility does not require sending power over the public grid, given that it is on the same premises as the charging facility. Thus the system relies on the utility power grid to the minimum extent possible.

The recharging system also provides protection for the vehicles undergoing recharging, as well as security for the energy storage devices and the alternative energy sources and the load management center, by maintaining these facilities within the premises of the vehicle charging station, or in close proximity thereto.

It seems apparent that making charging services widely available and integrated with other activities and vehicle trips taken by the public also serves another synergistic purpose. If charging is widely available at many locations, it is more feasible to use a smaller battery in the electric vehicle, knowing that it can be recharged conveniently at any stop, whereby the need for a larger battery for longer driving range is obviated.

### BRIEF DESCRIPTION OF THE DRAWING

FIG. 1 Illustrates the basic components of the electric vehicle recharging service of the invention.

### DETAILED DESCRIPTION OF THE INVENTION

The present invention generally comprises a system for providing charging services to a driving public that includes users of battery powered electrical vehicles, whether fully electric or plug-in hybrid electric.

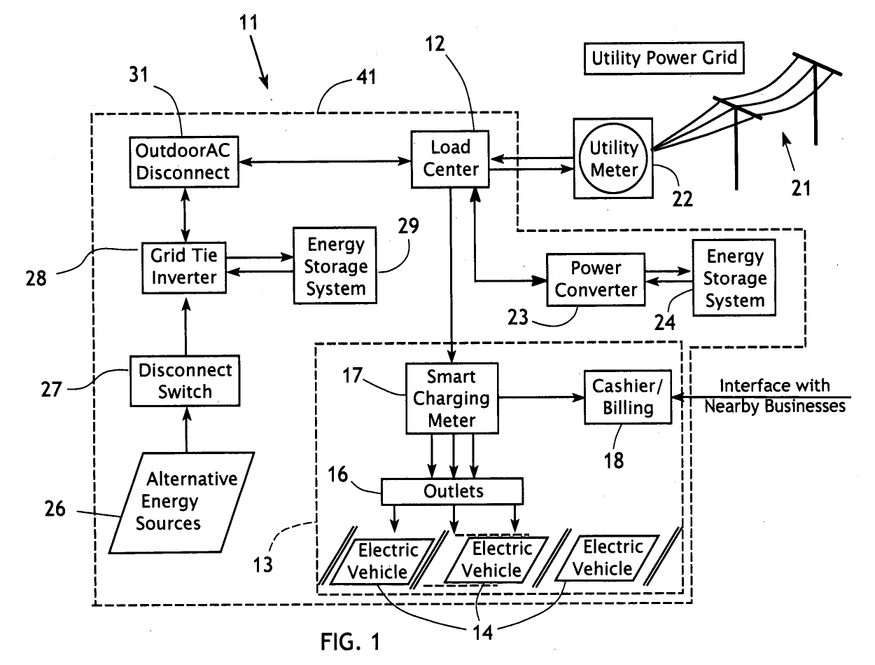

In general, with regard to FIG. 1 the charging system 11 includes a main electrical load center 12 that aggregates power from a plurality of sources and feeds power to a vehicle charging lot 13, where a plurality of electric vehicles 14 may be connected to charging outlets 16. The outlets 16 are preferably arrayed to serve separate vehicle parking spots within the charging lot 13, and are connected to a smart charging meter 17. The smart charging meter 17 tracks the identification of each vehicle 14 connected to the system, and data such as the amount of power delivered, time of charge, state of charge, and the like, as well as credit/debit/cash data to complete the transaction for payment for the recharging service. The transaction data is fed to a cashier/billing facility 18, which may comprise a credit/debit card point of sale machine, an attendant, or some other facility (see below).

A primary power supplier of the load center 12 is the utility power grid 21, which is connected through meter 22 to the load center. The load center optionally may also include an energy storage system 24 connected through a power converter 23 to receive grid power. The power converter 23 and energy storage system 24 are provided to store energy taken from the grid 21. This enables the charging system 11 to accumulate additional stored electrical power and thus vehicle charging capacity without demanding excessively high currents from the utility power grid, and to buy grid power during the least expensive hours when demand is down. The charging system thereby also acts to avoid overload or brown-out conditions on the power grid.

The energy storage systems 24 can store energy for a period of time and deliver electrical current levels sufficient to rapidly charge vehicles on demand while realizing a reduced average current demand on the utility power grid. The energy storage systems may comprise either batteries, super capacitors, kinetic energy storage such as flywheel devices, or co-generators from heat storage or heat sources.

Additionally one or more alternative energy sources 26 may be connected optionally to supply the load center 12. The alternative sources 26 may comprise any or all of the following: photovoltaic solar cells, wind power, tidal power, solar collector/steam turbine. The alternative sources 26 are connected through a disconnect switch 27 to one or more grid-tied inverters 28 which can direct power either to the grid 21 or another energy storage system 29. This energy storage system 29 may, according to demand, store and deliver and convert power to AC electricity that is synchronized to the power grid and delivered to the load center through another disconnect switch 31. Note that the alternative energy sources 26 may also transmit power to the grid during high power production times, such as photovoltaic solar cells during a sunny mid-day, and build up cost credits, which may be used at other times of low alternative power production, to purchase power back from the grid 21.

The composite power is then delivered and distributed through the smart charging meter 17 to electric vehicles 14. The smart charging meter can then bidirectionally exchange status, authorization and other information necessary to complete commercial delivery transactions with a cashier, who may be either a human or interactive computer. The smart charging meter 17 must also assess the state of charge of the vehicle battery in order to determine the optimum voltage and current to carry out the recharging task, and to detect when charging is complete. These factors may depend on the chemical composition of the vehicle battery, the no-load and full-load voltage output of the battery, limits on the rate of charge, and the like.

Note that the cashier function may be interfaced and combined with any business located proximate to the charging station. For example, a parking garage featuring the recharging station may add the cost of energy to the parking charge that is paid as the vehicle exits the parking facility. Likewise, restaurants or retail sales outlets or entertainment venues (cinema, sporting events, theatres) may-add the cost of the recharge service to the total sale upon checkout or other conclusion of the business transaction. Businesses may collaborate to offer linked services (e.g., free vehicle charge offered to restaurant dining patrons) and inducements, providing a way in which the charging system is integrated into the world of commerce, as well as the world of electrical power sources.

For example, it is assumed that an electrical vehicle driver will park the vehicle 14 proximate to a recharging outlet 16, most typically a three-pronged electrical plug or cable. In order to order a charge, the driver must swipe a credit/debit card at the outlet and establish a guarantee to pay. If that same card is presented at a nearby business establishment within the same time period, the transactions may be linked, special offers or discounts may be executed, and the final total determined and paid. This transaction coordination may be furthered by obtaining the VIN (vehicle identification number) from the outlet during recharging (by accessing the internal vehicle data bus), or by scanning for any RFID device on the vehicle, such as FastTrack™ or FastPass™.

Attention must be given to the regulatory requirements for recharging service providers. For example, the State of California Electric Code and California Building Code sections governing EV charging station installations states that chargers must have either a dedicated 40 A-240V ground-fault circuit interrupter (GFCI) circuit for a 3-to 8-hour charge; or a 15 A-120V GFCI circuit for a 10- to 15-hour charge. (120V charging stations are far less convenient for commercial charge system because of the long charge time.) A 240V circuit comprises a significant safety hazard, and must be protected from the vandalism and casual mischief that can be enabled by uncontrolled public contact. Thus, a major feature of the charging station 13 is that it is enclosed within a security perimeter 41 formed by physical barriers as well as CCTV surveillance or attendant monitoring. The security perimeter also preferably encloses any of the optional components of the system, such as the alternative energy sources 26, storage system 29 or 24, and the load center 12.

The foregoing description of the preferred embodiments of the invention has been presented for purposes of illustration and description. It is not intended to be exhaustive or to limit the invention to the precise form disclosed, and many modifications and variations are possible in light of the above teaching without deviating from the spirit and the scope of the invention. The embodiment described is selected to best explain the principles of the invention and its practical application to thereby enable others skilled in the art to best utilize the invention in various embodiments and with various modifications as suited to the particular purpose contemplated. It is intended that the scope of the invention be defined by the claims appended hereto.

What is claimed is:

1. A commercial recharging system for electric vehicles having rechargeable batteries, including:
a plurality of charging outlets, each adapted to connect to the battery of an electrically powered vehicle;
smart charging meter means for conducting electrical power to said plurality of charging outlets and for monitoring said charging outlets to determine customer data concerning the connection of an electrically powered vehicle to any of said plurality of charging outlets;
cashier means for receiving said customer data and generating a bill of sale for a recharging service carried out through any of said plurality of charging outlets, and for carrying out a credit/debit/cash transaction to complete the sale of the recharging service;
power supply means connected through said smart charging meter means to said plurality of outlets to deliver electrical power to the battery of an electric vehicle connected to a respective outlet.

2. The commercial recharging system of claim 1, wherein said plurality of charging outlets are arrayed within a charging lot having a plurality of vehicle parking spots and distributed one to each of said vehicle parking spots within the charging lot.

3. The commercial recharging system of claim 2, further including security means for protecting vehicles and recharging system equipment within said charging lot.

4. The commercial recharging system of claim 1, wherein said power supply means includes the electric power utility grid.

5. The commercial recharging system of claim 4, further including first energy storage means for receiving energy from said utility grid and storing said energy for later use by said commercial recharging system.

6. The commercial recharging system of claim 5, wherein said power supply means further includes at least one alternative energy source chosen from the group consisting of: photovoltaic solar cells, wind power, tidal power, waste heat cogeneration, and solar collector/steam turbine.

7. The commercial recharging system of claim 6, further including second energy storage means for receiving energy from said at least one alternative energy source grid and storing said alternative energy for later use by said commercial recharging system.

8. The commercial recharging system of claim 7, further including load management means connected to said first and second energy storage means, said at least one alternative energy source, and said utility grid, said load management means controlling the flow of electrical power from said sources and storage means to said plurality of charging outlets.

9. The commercial recharging system of claim 8, wherein said plurality of charging outlets, said energy storage means, and said at least one alternative energy source are arrayed within a charging lot, and further including security means for protecting vehicles and recharging system equipment within said charging lot.

10. The commercial recharging system of claim 2, wherein said cashier means includes an attendant worker to perform he credit/debit/cash transaction.

11. The commercial recharging system of claim 2, further including interface means for combining said cashier means with a separate commercial business proximate to said charging lot, whereby said credit/debit/cash transaction is carried out by said separate commercial business.

12. The commercial recharging system of claim 11, wherein said separate commercial business comprises a parking lot for vehicles.

13. The commercial recharging system of claim 11, wherein said separate business is a type chosen from the group consisting of: restaurants, retail sales outlets, transit terminals, and venues for entertainment such as sporting events, cinema, and theatre.

14. The commercial recharging system of claim 13, further including linked services and sales inducements offered by said separate commercial business to combine with said credit/debit/cash transaction.
